(19) United States
(12) Patent Application Publication
(10) Pub. No.: US 2008/0062759 A1
(43) Pub. Date: Mar. 13, 2008

(54) FLASH MEMORY DEVICE, METHOD OF OPERATING A FLASH MEMORY DEVICE AND METHOD FOR MANUFACTURING THE SAME DEVICE

(76) Inventor: Jin-Hyo Jung, Gyeonggi-do (KR)

Correspondence Address: SHERR & NOURSE, PLLC, 620 HERNDON PARKWAY, SUITE 200, HERNDON, VA, 20170, US

(21) Appl. No.: 11/844,510

(22) Filed: Aug. 24, 2007

(30) Foreign Application Priority Data
Sep. 12, 2006 (KR) 10-2006-0087762

(51) Int. Cl. G11C 11/34; H01L 21/336; H01L 29/788

(52) U.S. Cl. 365/185.2; 257/316; 438/265; 257/E29.3; 257/E21.422

(57) ABSTRACT

A flash memory device includes a semiconductor substrate having a field oxide layer defining an active area; a gate oxide layer formed over parts of the active area of the semiconductor substrate; a coupling oxide layer formed over both the semiconductor substrate and a sidewall of the polygate; a floating gate formed over the coupling oxide layer; and a source/drain area formed in an external lower semiconductor substrate of the planar floating gate.

The present application claims priority under 35 U.S.C. 119 to Korean Patent Application No. 10-2006-0087762 (filed on Sep. 12, 2006), which is hereby incorporated by reference in its entirety.

### BACKGROUND

Flash memory is devised to incorporate the aspects of may be a nonvolatile semiconductor memory which includes an erasable programmable read only memory (EPROM) and/or electrically erasable programmable read only memory (EEPROM). Flash memory may provide electrical data that may be programmed and erased at a low production cost due to its small size and simple fabrication process.

Flash memory may be a non-volatile memory having electrical data incapable of being erased although the flash memory is powered off. However, the programming and deleting actions of information may be electrically executed easily in the system, so that the flash memory exhibits characteristics of volatile semiconductor memory, such as random access memory (RAM). Therefore, the flash memory has been widely used for memory cards or memory units for replacing hard discs of portable office-automation devices.

Data is programmed in flash memory though the injection of hot electrons. In particular, when hot electrons are generated in a channel due to a difference in potential between a source and a drain, some electrons acquiring energy of at least 3.1 electron-Volts (eV), which is a potential barrier between a gate polycrystalline silicon and an oxide layer, move to and are stored in a floating gate by a high electric field applied to a control gate.

Therefore, the hot electrons may deteriorate a general metal oxide semiconductor (MOS) device insofar as the MOS has been designed to maximally restrict hot electrons. On the other hand, the flash memory has been designed to generate hot electrons.

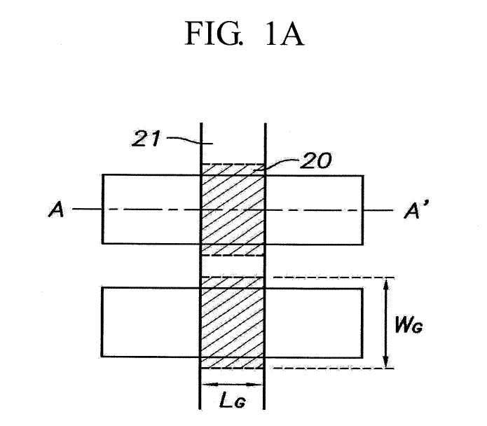

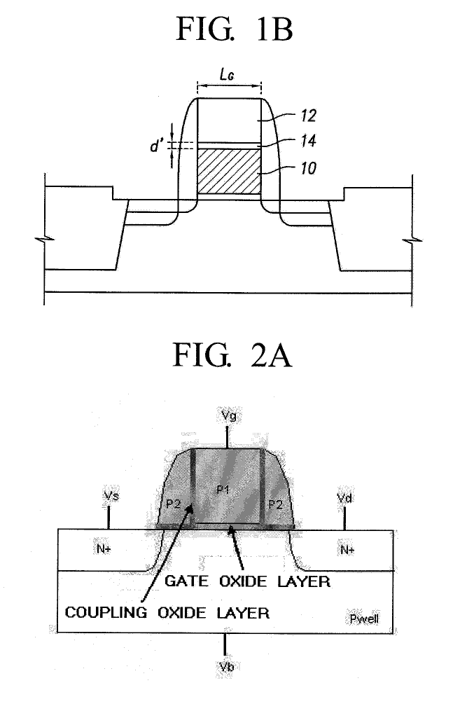

Illustrated in example FIGS. 1A and 1B are a flash memory device having a silicon substrate and a gate composed of a two-layered polycrystalline silicon layer. The gate includes a lower gate such as floating gate 10 provided adjacent to the silicon substrate, an upper gate stacked above floating gate 10 such as control gate 12, and insulation layer 14 interposed between floating gate 10 and control gate 12. Floating gate 10 is not connected to an external part, and acts as a storage node of electrons. Control gate 12 acts as a gate for a general MOS transistor.

The flash memory device illustrated in examples FIGS. 1A and 1B can be implemented in a very small-sized cell so that it can also be properly used to implement the high-density EEPROM. However, floating gate 10 must be formed under control gate 12, and therefore, complicates the overall fabrication process. Moreover, the flash memory device is not compatible with the CMOS fabrication process, and thus, is difficult to add to a logical element.

### SUMMARY

In accordance with embodiments, a flash memory device including a semiconductor substrate having a field oxide layer defining an active area; a gate oxide layer formed on some parts of the active area of the semiconductor substrate; a coupling oxide layer formed on and/or over the semiconductor substrate and a sidewall of a polygate; a floating gate formed on and/or over the coupling oxide layer; and a source/drain area formed in an external lower semiconductor substrate of the floating gate.

In accordance with embodiments, a method for operating a flash memory device including applying a reference voltage to a polygate; applying a positive voltage to a drain; measuring a variation in a threshold voltage of a specific part corresponding to a source/drain extended area located under a planar floating gate; and recognizing the flash memory device as a program status if it is determined that the threshold voltage increases during the application of the positive voltage.

In accordance with embodiments, a method for manufacturing a flash memory device including forming a gate oxide layer on and/or over a semiconductor substrate; forming a polygate on and/or over the gate oxide layer; forming a coupling oxide layer on and/or over the semiconductor substrate and a sidewall of the polygate; forming a planar floating gate on and/or over the coupling oxide layer; and forming a source/drain area in an external lower semiconductor substrate of the planar floating gate.

### DRAWINGS

Example FIGS. 1A and 1B illustrate a flash memory device.

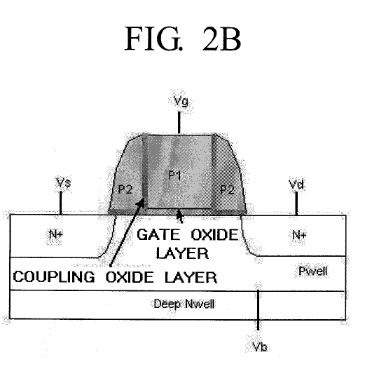

Example FIGS. 2A and 2B illustrate a planar floating gate EEPROM, in accordance with embodiments.

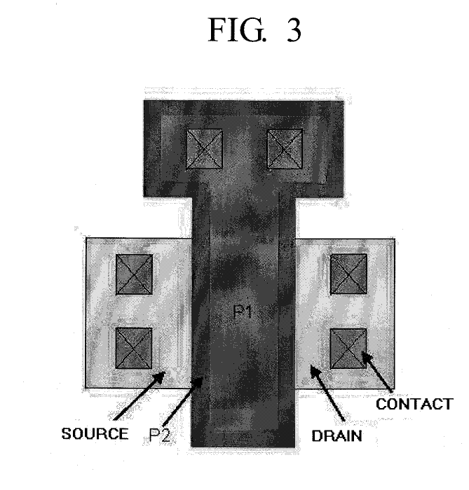

Example FIG. 3 illustrates a planar floating gate EEPROM, in accordance with embodiments.

### DESCRIPTION

As illustrated in example FIGS. 2A and 2B, a flash memory including a field oxide layer deposited over a semiconductor substrate. The field oxide layer may define an active area. A gate oxide layer is deposited over the semiconductor substrate. Polygate P1 is deposited over the gate oxide layer, and may act as a control gate and a select gate of a floating gate EEPROM. A coupling oxide layer is deposited over both the semiconductor substrate and a sidewall of the polygate. Planar floating gate P2 is deposited over the coupling oxide layer. Planar floating gate P2 may be similar to the floating gate of a floating gate EEPROM with at least an exception that it controls a source/drain extended area. A source/drain area is formed in an external lower semiconductor substrate of the planar floating gate. Example FIG. 2B further illustrates a triple well structure for enclosing a P-well with a deep N-well to strengthen the isolation of the P-well.

As illustrated in example FIG. 3, in accordance with embodiments, planar floating gate EEPROM may include the same structure as that of a MOS transistor. However, instead of having polygate P1 enclosed by a sidewall spacer as in the MOS transistor, the planar floating gate EEPROM includes a sidewall of polygate P1 enclosed by planar floating gate P2. Moreover, impurity ions for forming a source/drain extended area (i.e., LDD area) are not implanted beneath planar floating gate P2.

In accordance with embodiments, a fabrication process for the planar floating gate EEPROM utilizes a CMOS fabrication process with the exception that formation of a sidewall spacer may be exchanged for the formation of sidewall planar floating gate P2. In particular, a polysilicon deposition and etching back process are performed instead of the formation of a sidewall spacer so that the sidewall of polygate P1 is enclosed by planar floating gate P2. Accordingly, a planar floating gate EEPROM can be generated by a process that is simplistic in comparison to that of a floating gate EEPROM. Moreover, the planar floating gate EEPROM in accordance with embodiments may be fabricated in the form of a general MOS transistor. Meaning, a planar floating gate EEPROM can be fabricated at low costs and at a small cell size that is comparable to that of a floating gate EEPROM.

In accordance with embodiments, a method for manufacturing a flash memory device includes forming a gate oxide layer on and/or over a semiconductor substrate. Polygate P1 is deposited on and/or over the gate oxide layer. A coupling oxide layer is deposited on and/or over both the semiconductor substrate and a sidewall of the polygate. Planar floating gate P2 is formed on the coupling oxide layer. A source/drain area is formed in an external lower semiconductor substrate of the planar floating gate.

In accordance with embodiments, a method for operating a planar floating gate EEPROM includes the following:

Program Method
F/N tunneling (Fowler/Nordheim Tunneling) method: Vg=+Vp1, Vd=Vs=GND, Vb=Floating or GND
Hot electron injection method: Vg=+Vp2, Vd=+Vd1, Vs=Vb=GND

Erasing Method
F/N tunneling method 1: Vg=−Ve1, Vd=Vs=GND, Vb=Floating or GND
F/N tunneling method 2: Vg=GND, Vd=Vs=−Ve1, Vb=Floating or GND

Reading Method

−Vg=+Vref,Vd=+Vd2,Vs=Vb=GND

In accordance with embodiments, the method injects electrons in planar floating gate P2 using any one of the F/N tunneling method and the hot electron injection process. The erasing process removes the electrons injected in planar floating gate P2 by the F/N tunneling process. In order to recognize the program/erasing status, “+Vref” corresponding to a reference voltage is applied to polygate P1, and an appropriate positive voltage is applied to the drain. Provided that the program status caused by the electrons injected into planar floating gate P2 is established, a threshold voltage corresponding to the source/drain extended area located under planar floating gate P2 may increase. Accordingly, since the threshold voltage of planar floating gate P2 is much higher than the reference voltage although the reference voltage has been applied to polygate P1, it may be unable to invert the source/drain extended area located under planar floating gate P2, so that current does not flow. As a result, the program status is detected.

Provided that the erasing status caused by electrons removed from planar floating gate P2 is established, the threshold voltage of a specific part corresponding to the source/drain extended area under planar floating gate P2 is lowered. Consequently, if the reference voltage is applied to polygate P1, the threshold voltage of planar floating gate P2 is lower than the reference voltage, so that the source/drain extended area located under planar floating gate P2 is inverted, and the current flows in the direction from the drain to the source. As a result, the erasing status is detected.

The voltage coupled to planar floating gate P2 is determined by a coupling ratio. The coupling ratio is indicative of the ratio of capacitance between polygate P1 and planar floating gate P2 to the other capacitance between planar floating gate P2 and the source/drain area. In accordance with embodiments, the capacitance between the source/drain area and planar floating gate P2 in the planar floating gate EEPROM may be substantially less than the capacitance between a source/drain area and a floating gate such that the coupling ratio may be reach 0.8 or more.

In accordance with embodiments, a flash memory is advantageous for having the capability to produce a small-sized cell area in a very simplistic fabrication process. A low-cost high-density memory device can be manufactured utilizing a CMOS fabrication and thus, can be easily added to a logic element because it without any change.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a semiconductor substrate;
a field oxide layer formed over the semiconductor substrate, wherein the field oxide layer defines an active area;
a gate oxide layer formed over the semiconductor substrate;
a polygate formed over the gate oxide layer;
a coupling oxide layer formed over both the semiconductor substrate and a sidewall of the polygate;
a planar floating gate formed over the coupling oxide layer; and
a source/drain area formed in an external lower semiconductor substrate of the planar floating gate.

2. The apparatus of claim 1, wherein the semiconductor substrate includes a deep well located at a lower area thereof, the deep well including an opposite conductive well at an upper part of the deep well.

3. The apparatus of claim 1, wherein the polygate acts as a control gate and a select gate.

4. The apparatus of claim 1, where the sidewall of the polygate is enclosed by the planar floating gate.

5. The apparatus of claim 1, wherein the gate oxide layer is formed over parts of the active area of the semiconductor substrate.

6. A method of operating a flash memory device comprising:
applying a reference voltage to a polygate;
applying a positive voltage to a drain;
measuring a variation in a threshold voltage of a specific part corresponding to a source/drain extended area located under a planar floating gate; and
recognizing the flash memory device as a program status if the threshold voltage increases after measuring the variation in the threshold voltage.

7. The method of claim 6, further comprising recognizing the flash memory device as an erasing status if the threshold voltage decreases after measuring the variation in the threshold voltage.

8. The method of claim 6, wherein the flash memory device injects electrons in the planar floating gate using a Fowler/Nordheim tunneling method.

9. The method of claim 6, wherein the flash memory device injects electrons in the planar floating gate using a hot electron injection method.

10. The method of claim 6, wherein the flash memory device deducts electrons from the planar floating gate using a Fowler/Nordheim (F/N) tunneling method in an erasing status.

11. A method comprising:
forming a gate oxide layer over a semiconductor substrate;
forming a polygate over the gate oxide layer;
forming a coupling oxide layer over both the semiconductor substrate and a sidewall of the polygate;
forming a planar floating gate over the coupling oxide layer; and
forming a source/drain area in an external lower semiconductor substrate of the planar floating gate.

12. The method of claim 11, wherein the planar floating gate is formed to enclose said sidewall of the polygate.

13. The method of claim 12, wherein the planar floating gate is formed using a polysilicon deposition and etching back process.

14. The method of claim 11, wherein the semiconductor substrate includes a deep well located at a lower area thereof.

15. The method of claim 14, wherein the deep well includes an opposite conductive well at an upper area of the deep well.

16. The method of claim 11, wherein the polygate acts as a control gate and a select gate.

17. The method of claim 11, wherein the polygate acts as a select gate.

18. The method of claim 11, wherein the polygate acts as a control gate and a select gate.

19. The method of claim 11, wherein the gate oxide layer is formed over parts of the active area of the semiconductor substrate.
